(19) United States
(12) Patent Application Publication
(10) Pub. No.: US 2026/0040902 A1
(43) Pub. Date: Feb. 5, 2026

(54) TEST STRUCTURE

(71) Applicant: Winbond Electronics Corp., Taichung City (TW)

(72) Inventors: Shih-Ming Wang, Tainan City (TW); Jun-Jie Pang, Taichung City (TW)

(73) Assignee: Winbond Electronics Corp., Taichung City (TW)

(21) Appl. No.: 19/071,759

(22) Filed: Mar. 6, 2025

(30) Foreign Application Priority Data
Aug. 2, 2024 (TW) 113128934

(51) Int. Cl. H01L 21/66; G01R 31/26

(52) U.S. Cl. CPC H01L 22/32; G01R 31/2601

(57) ABSTRACT

A test structure including the following members is provided. A substrate includes an array region and a peripheral region. The array region has a first side and a second side opposite to each other. An isolation structure is located in the substrate. The isolation structure defines active regions in the substrate of the array region. Word lines pass through the active regions and are insulated from the substrate. The word lines include first word lines and second word lines arranged alternately. First contacts are electrically connected to the first word lines. Second contacts are electrically connected to the second word lines. The first contacts and the second contacts are arranged in a staggered manner. First conductive lines are electrically connected to the first contacts. Second conductive lines are electrically connected to the second contacts. The second conductive lines are extended from the peripheral region into the array region.

### CROSS-REFERENCE TO RELATED APPLICATION

This application claims the priority benefit of Taiwan application serial no. 113128934, filed on Aug. 2, 2024. The entirety of the above-mentioned patent application is hereby incorporated by reference herein and made a part of this specification.

### BACKGROUND OF THE INVENTION

### Field of the Invention

The invention relates to a semiconductor structure, and in particular to a test structure.

### Description of Related Art

Currently, different test structures are used to measure the resistances of word lines and the element characteristics of transistors. However, since different test structures are used to measure the resistances of the word lines and the element characteristics (such as threshold voltage (Vt) and on-current ratio (Ion)) of the transistors, the effect of the resistances of the word lines on the element characteristics of the transistors may not be accurately obtained.

### SUMMARY OF THE INVENTION

The invention provides a test structure that may accurately obtain the influence of the resistances of word lines on the element characteristics of transistors.

The invention provides a test structure including a substrate, an isolation structure, a plurality of word lines, a plurality of first contacts, a plurality of second contacts, a plurality of first conductive lines, and a plurality of second conductive lines. The substrate includes an array region and a peripheral region. The array region has a first side and a second side opposite to each other. The isolation structure is located in the substrate. The isolation structure defines a plurality of active regions in the substrate of the array region. The plurality of word lines pass through the plurality of active regions and are insulated from the substrate. The plurality of word lines include a plurality of first word lines and a plurality of second word lines arranged alternately. The plurality of first contacts are located at the first side of the array region and electrically connected to the plurality of first word lines. The plurality of second contacts are located at the first side of the array region and electrically connected to the plurality of second word lines. The plurality of first contacts and the plurality of second contacts are arranged in a staggered manner. The plurality of first conductive lines are electrically connected to the plurality of first contacts. The plurality of second conductive lines are electrically connected to the plurality of second contacts. The plurality of second conductive lines are extended from the peripheral region into the array region.

Based on the above, in the test structure provided by the invention, the plurality of word lines pass through the plurality of active regions and are insulated from the substrate. The plurality of word lines include the plurality of first word lines and the plurality of second word lines arranged alternately. The plurality of first contacts are located at the first side of the array region and electrically connected to the plurality of first word lines. The plurality of second contacts are located at the first side of the array region and electrically connected to the plurality of second word lines. The plurality of first contacts and the plurality of second contacts are arranged in a staggered manner. The plurality of first conductive lines are electrically connected to the plurality of first contacts. The plurality of second conductive lines are electrically connected to the plurality of second contacts. The plurality of second conductive lines are extended from the peripheral region into the array region. Via the layout design of the test structure, the resistances of the word lines and the element characteristics (such as critical voltage (Vt) and on-current ratio (Ion)) of the transistors may be measured using the same test structure. Therefore, the influence of the resistances of the word lines on the element characteristics of the transistors may be accurately obtained. In addition, the resistances of different word lines may be measured to check whether there is a mismatch issue in the resistances of different word lines. If the resistances of different word lines do not match, there may be an issue in the process of the plurality of word lines in the chip, so that the process issues may be found and solved.

In order to make the aforementioned features and advantages of the disclosure more comprehensible, embodiments accompanied with figures are described in detail below.

### BRIEF DESCRIPTION OF THE DRAWINGS

FIG. 1 is a top view of a test structure according to some embodiments of the invention.

FIG. 2 is a cross-sectional view along section line I-I′ and section line II-II′ in FIG. 1.

### DESCRIPTION OF THE EMBODIMENTS

Embodiments are provided hereinafter and described in detail with reference to figures. However, the embodiments provided are not intended to limit the scope of the invention. In order to facilitate understanding, the same members are described with the same reference numerals in the following description. In addition, the drawings are for illustration purposes only and are not drawn to original scale. Also, the features in the upper view are not drawn to the same scale as those in the cross-sectional view. In fact, the dimensions of the various features may be arbitrarily increased or reduced for clarity of discussion.

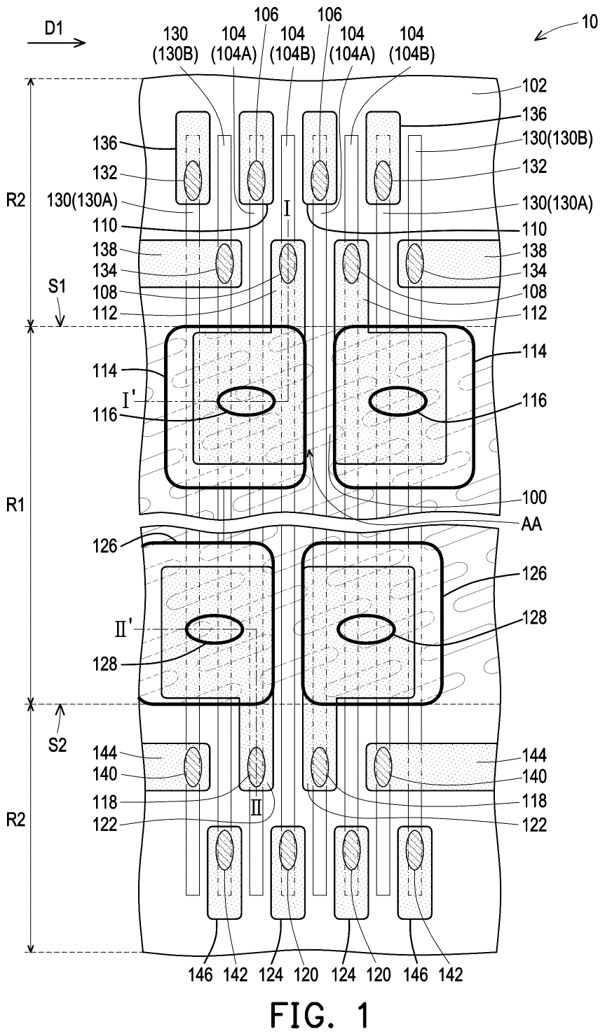

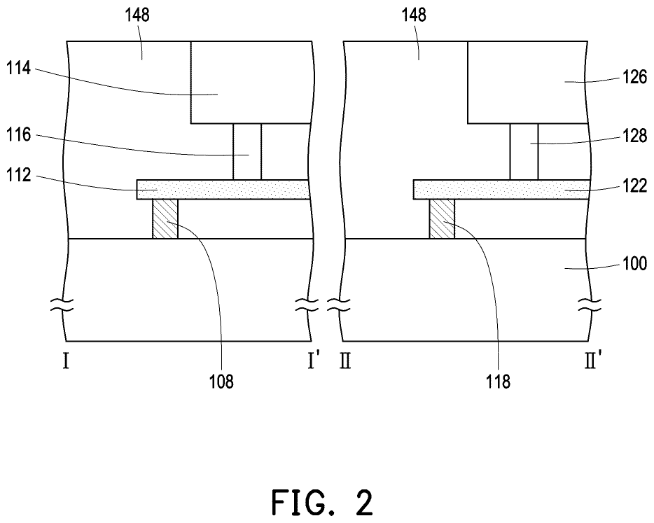

FIG. 1 is a top view of a test structure according to some embodiments of the invention. FIG. 2 is a cross-sectional view along section line I-I′ and section line II-II′ in FIG. 1. In the cross-sectional view of FIG. 2, some members in the top view of FIG. 1 are omitted to simplify the drawing.

Referring to FIG. 1 and FIG. 2, a test structure 10 includes a substrate 100, an isolation structure 102, a plurality of word lines 104, a plurality of contacts 106, a plurality of contacts 108, a plurality of conductive lines 110, and a plurality of conductive lines 112. In some embodiments, the test structure 10 may be a test key structure. In some embodiments, the test structure 10 may be used to test element characteristics in a test chip. For example, the test structure 10 may be used to test element characteristics of a dynamic random-access memory (DRAM) in the chip. In some embodiments, the test structure 10 may be located in the scribe line region of the wafer rather than in the chip region of the wafer. In some other embodiments, the test structure 10 may be made into a module test key and independently divided into one chip region. In some other embodiments, the test structure 10 may be located in a test region of the chip region.

The substrate 100 includes an array region R1 and a peripheral region R2. The array region R1 has a first side S1 and a second side S2 opposite to each other. In some embodiments, the substrate 100 may be a semiconductor substrate, such as a silicon substrate.

The isolation structure 102 is located in the substrate 100. The isolation structure 102 defines a plurality of active regions AA in the substrate 100 of the array region R1. In some embodiments, the isolation structure 102 is, for example, a shallow trench isolation (STI) structure. In some embodiments, the material of the isolation structure 102 is, for example, an oxide (such as silicon oxide).

The plurality of word lines 104 pass through the plurality of active regions AA and are insulated from the substrate 100. For example, the plurality of word lines 104 may be insulated from substrate 100 by a dielectric layer (not shown) and/or the isolation structure 102. In addition, the plurality of word lines 104 may further be extended into the peripheral region R2. The plurality of word lines 104 include a plurality of word lines 104A and a plurality of word lines 104B arranged alternately. In some embodiments, the material of the plurality of word lines 104 is, for example, metal (such as tungsten or titanium), titanium nitride, doped polysilicon, or a combination thereof. In some embodiments, the word lines 104 may be multi-layer stack structures including a barrier layer and a conductive layer.

In some embodiments, the plurality of word lines 104 may be buried word lines. In some embodiments, the buried word lines may be word lines buried in the substrate 100 and the isolation structure 102. In some embodiments, the plurality of word lines 104 may be planar word lines. In some embodiments, the planar word lines may be word lines located on the top surface of the substrate 100 and the top surface of the isolation structure 102. In some embodiments, as the size of the test structure 10 continues to shrink, the plurality of word lines 104 may be formed by a litho-etch-litho-etch (LELE) process or a self-aligned double patterning (SADP) process.

The plurality of contacts 106 are located at the first side S1 of the array region R1 and electrically connected to the plurality of word lines 104A. The plurality of contacts 108 are located at the first side S1 of the array region R1 and electrically connected to the plurality of word lines 104B. The plurality of contacts 106 and the plurality of contacts 108 are arranged in a staggered manner. The plurality of contacts 106 and the plurality of contacts 108 may be located in the peripheral region R2. The plurality of contacts 108 may be located between the plurality of contacts 106 and the array region R1. In some embodiments, the plurality of contacts 106 and the plurality of contacts 108 may be single-layer structures or multi-layer structures. In some embodiments, the material of the plurality of contacts 106 and the plurality of contacts 108 is, for example, tungsten, titanium, titanium nitride, or a combination thereof. In some embodiments, the plurality of contacts 106 and the plurality of contacts 108 may originate from the same material layer. That is, the plurality of contacts 106 and the plurality of contacts 108 may be formed simultaneously via the same process.

The plurality of conductive lines 110 are electrically connected to the plurality of contacts 106. The plurality of conductive lines 110 may be located in the peripheral region R2 and not located in the array region R1. The plurality of contacts 106 may be located between the plurality of conductive lines 110 and the plurality of word lines 104A. The plurality of conductive lines 112 are electrically connected to the plurality of contacts 108. The plurality of conductive lines 112 are extended from the peripheral region R2 into the array region R1. The plurality of contacts 108 may be located between the plurality of conductive lines 112 and the plurality of word lines 104B. In some embodiments, the plurality of conductive lines 110 and the plurality of conductive lines 112 may be single-layer structures or multi-layer structures. In some embodiments, the material of the plurality of conductive lines 110 and the plurality of conductive lines 112 is, for example, tungsten, aluminum, copper, titanium, titanium nitride, tantalum, tantalum nitride, or a combination thereof. In some embodiments, the plurality of conductive lines 110 and the plurality of conductive lines 112 may originate from the same material layer. That is, the plurality of conductive lines 110 and the plurality of conductive lines 112 may be formed simultaneously via the same process.

The test structure 10 may further include a plurality of conductive lines 114 and a plurality of contacts 116. The plurality of conductive lines 114 are electrically connected to the plurality of conductive lines 112. In some embodiments, the material of the plurality of conductive lines 114 is, for example, tungsten, aluminum, copper, titanium, titanium nitride, tantalum, tantalum nitride, or a combination thereof. The plurality of contacts 116 are located between the plurality of conductive lines 114 and the plurality of conductive lines 112. The plurality of contacts 116 are electrically connected to the plurality of conductive lines 114 and the plurality of conductive lines 112. The plurality of conductive lines 114 and the plurality of contacts 116 may be located in the array region R1. In some embodiments, the material of the plurality of contacts 106 is, for example, tungsten, titanium, titanium nitride, or a combination thereof.

The test structure 10 may further include a plurality of contacts 118, a plurality of contacts 120, a plurality of conductive lines 122, and a plurality of conductive lines 124. The plurality of contacts 118 are located at the second side S2 of the array region R1 and electrically connected to the plurality of word lines 104A. The plurality of contacts 120 are located at the second side S2 of the array region R1 and electrically connected to the plurality of word lines 104B. The plurality of contacts 118 and the plurality of contacts 120 are arranged in a staggered manner. The plurality of contacts 118 and the plurality of contacts 120 may be located in the peripheral region R2. The plurality of contacts 118 may be located between the plurality of contacts 120 and the array region R1. In some embodiments, the plurality of contacts 118 and the plurality of contacts 120 may be single-layer structures or multi-layer structures. In some embodiments, the material of the plurality of contacts 118 and the plurality of contacts 120 is, for example, tungsten, titanium, titanium nitride, or a combination thereof.

The plurality of conductive lines 122 are electrically connected to the plurality of contacts 118. The plurality of conductive lines 122 are extended from the peripheral region R2 into the array region R1. The plurality of contacts 118 may be located between the plurality of conductive lines 122 and the plurality of word lines 104A. The plurality of conductive lines 124 are electrically connected to the plurality of contacts 120. In some embodiments, the plurality of conductive lines 124 may be located in the peripheral region R2 and not located in the array region R1. The plurality of contacts 120 may be located between the plurality of conductive lines 124 and the plurality of word lines 104B. In some embodiments, the plurality of conductive lines 122 and the plurality of conductive lines 124 may be single-layer structures or multi-layer structures. In some embodiments, the material of the plurality of conductive lines 122 and the plurality of conductive lines 124 is, for example, tungsten, aluminum, copper, titanium, titanium nitride, tantalum, tantalum nitride, or a combination thereof.

The test structure 10 may further include a plurality of conductive lines 126 and a plurality of contacts 128. The plurality of conductive lines 126 are electrically connected to the plurality of conductive lines 122. In some embodiments, the material of the plurality of conductive lines 126 is, for example, tungsten, aluminum, copper, titanium, titanium nitride, tantalum, tantalum nitride, or a combination thereof. The plurality of contacts 128 are located between the plurality of conductive lines 126 and the plurality of conductive lines 122. The plurality of contacts 128 are electrically connected to the plurality of conductive lines 126 and the plurality of conductive lines 122. The plurality of conductive lines 126 and the plurality of contacts 128 may be located in the array region R1. In some embodiments, the material of the plurality of contacts 128 is, for example, tungsten, titanium, titanium nitride, or a combination thereof.

The test structure 10 may further include a plurality of dummy word lines 130, a plurality of contacts 132, a plurality of contacts 134, a plurality of conductive lines 136, a plurality of conductive lines 138, a plurality of contacts 140, a plurality of contacts 142, a plurality of conductive lines 144, and a plurality of conductive lines 146. The plurality of dummy word lines 130 pass through the plurality of active regions AA and are insulated from the substrate 100. For example, the plurality of dummy word lines 130 may be insulated from substrate 100 by a dielectric layer (not shown) and/or the isolation structure 102. In addition, the plurality of dummy word lines 130 may further be extended into the peripheral region R2. The plurality of dummy word lines 130 include a plurality of dummy word lines 130A and a plurality of dummy word lines 130B arranged alternately. In some embodiments, the material of the plurality of dummy word lines 130 is, for example, metal (such as tungsten or titanium), titanium nitride, doped polysilicon, or a combination thereof. In some embodiments, the dummy word lines 130 may be multi-layer stack structures including a barrier layer and a conductive layer.

In some embodiments, the plurality of dummy word lines 130 may be buried word lines or planar word lines. In some embodiments, as the size of the test structure 10 continues to shrink, the plurality of dummy word lines 130 may be formed by an LELE process or a SADP process.

The plurality of contacts 132 are located at the first side S1 of the array region R1 and electrically connected to the plurality of dummy word lines 130A. The plurality of contacts 134 are located at the first side S1 of the array region R1 and electrically connected to the plurality of dummy word lines 130B. The plurality of contacts 132 and the plurality of contacts 134 are arranged in a staggered manner. The plurality of contacts 132 and the plurality of contacts 134 may be located in the peripheral region R2. The plurality of contacts 134 may be located between the plurality of contacts 132 and the array region R1. The plurality of contacts 132 are aligned with the plurality of contacts 106 in an arrangement direction D1 of the plurality of dummy word lines 130. The plurality of contacts 134 are aligned with the plurality of contacts 108 in the arrangement direction D1 of the plurality of dummy word lines 130. In some embodiments, the plurality of contacts 132 and the plurality of contacts 134 may be single-layer structures or multi-layer structures. In some embodiments, the material of the plurality of contacts 132 and the plurality of contacts 134 is, for example, tungsten, titanium, titanium nitride, or a combination thereof.

The plurality of conductive lines 136 are electrically connected to the plurality of contacts 132, and the plurality of contacts 132 may be located between the plurality of conductive lines 136 and the plurality of dummy word lines 130A. The plurality of conductive lines 138 are electrically connected to the plurality of contacts 134, and the plurality of contacts 134 may be located between the plurality of conductive lines 138 and the plurality of dummy word lines 130B. The plurality of conductive lines 136 and the plurality of conductive lines 138 may be located in the peripheral region R2 and not located in the array region R1. In some embodiments, the plurality of conductive lines 136 and the plurality of conductive lines 138 may be single-layer structures or multi-layer structures. In some embodiments, the material of the plurality of conductive lines 136 and the plurality of conductive lines 138 is, for example, tungsten, aluminum, copper, titanium, titanium nitride, tantalum, tantalum nitride, or a combination thereof.

The plurality of contacts 140 are located at the second side S2 of the array region R1 and electrically connected to the plurality of dummy word lines 130A. The plurality of contacts 142 are located at the second side S2 of the array region R1 and electrically connected to the plurality of dummy word lines 130B. The plurality of contacts 140 and the plurality of contacts 142 are arranged in a staggered manner. The plurality of contacts 140 and the plurality of contacts 142 may be located in the peripheral region R2. The plurality of contacts 140 may be located between the plurality of contacts 142 and the array region R1. The plurality of contacts 140 are aligned with the plurality of contacts 118 in the arrangement direction D1 of the plurality of dummy word lines 130. The plurality of contacts 142 are aligned with the plurality of contacts 120 in the arrangement direction D1 of the plurality of dummy word lines 130. In some embodiments, the plurality of contacts 140 and the plurality of contacts 142 may be single-layer structures or multi-layer structures. In some embodiments, the material of the plurality of contacts 140 and the plurality of contacts 142 is, for example, tungsten, titanium, titanium nitride, or a combination thereof.

The plurality of conductive lines 144 are electrically connected to the plurality of contacts 140, and the plurality of contacts 140 may be located between the plurality of conductive lines 144 and the plurality of dummy word lines 130A. The plurality of conductive lines 146 are electrically connected to the plurality of contacts 142, and the plurality of contacts 142 may be located between the plurality of conductive lines 146 and the plurality of dummy word lines 130B. In some embodiments, the plurality of conductive lines 144 and the plurality of conductive lines 146 may be located in the peripheral region R2 and not located in the array region R1. In some embodiments, the plurality of conductive lines 144 and the plurality of conductive lines 146 may be single-layer structures or multi-layer structures. In some embodiments, the material of the plurality of conductive lines 144 and the plurality of conductive lines 146 is, for example, tungsten, aluminum, copper, titanium, titanium nitride, tantalum, tantalum nitride, or a combination thereof.

Referring to FIG. 2, the test structure 10 may further include a dielectric layer 148. The dielectric layer 148 is located on the substrate 100. The contacts 108, the conductive lines 112, the contacts 116, the conductive lines 114, the contacts 118, the conductive lines 122, the contacts 128, and the conductive lines 126 may be located in the dielectric layer 148. In some embodiments, the dielectric layer 148 may be a multi-layer structure. In some embodiments, the material of the dielectric layer 148 may include an oxide (such as silicon oxide).

Moreover, the test structure 10 may further include a desired member (such as a source region, a drain region, a conductive line connected to the source region, and a conductive line connected to the drain region, etc.) for measuring the element characteristics of a semiconductor element (such as a transistor and/or a memory), which is not described herein.

In some embodiments, when the resistances of the word lines 104 and the element characteristics of the transistors are measured, an operating voltage may be applied to the word lines 104, and a common voltage may be applied to the dummy word lines 130 to prevent interference.

Based on the above, in the test structure 10 of the above embodiments, the plurality of word lines 104 pass through the plurality of active regions AA and are insulated from the substrate 100. The plurality of word lines 104 include the plurality of word lines 104A and the plurality of word lines 104B arranged alternately. The plurality of contacts 106 are located at the first side S1 of the array region R1 and electrically connected to the plurality of word lines 104A. The plurality of contacts 108 are located at the first side S1 of the array region R1 and electrically connected to the plurality of word lines 104B. The plurality of contacts 106 and the plurality of contacts 108 are arranged in a staggered manner. The plurality of conductive lines 110 are electrically connected to the plurality of contacts 106. The plurality of conductive lines 112 are electrically connected to the plurality of contacts 108. The plurality of conductive lines 112 are extended from the peripheral region into the array region R1. Via the layout design of the test structure 10, the resistance of the word lines 104 and the element characteristics (such as critical voltage (Vt) and on-current ratio (Ion)) of the transistors may be measured using the same test structure 10. Therefore, the influence of the resistances of the word lines 104 on the element characteristics of the transistors may be accurately obtained. In addition, the resistances of different word lines 104 may be measured to check whether there is a mismatch issue in the resistances of different word lines 104. If the resistances of different word lines 104 do not match, there may be an issue in the process of the plurality of word lines 104 in the chip, so that the process issues may be found and solved.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A test structure, comprising:
a substrate comprising an array region and a peripheral region, wherein the array region has a first side and a second side opposite to each other;
an isolation structure located in the substrate, wherein the isolation structure defines a plurality of active regions in the substrate of the array region; and
a plurality of word lines passing through the plurality of active regions and insulated from the substrate, wherein the plurality of word lines comprise a plurality of first word lines and a plurality of second word lines arranged alternately;
a plurality of first contacts located at the first side of the array region and electrically connected to the plurality of first word lines;
a plurality of second contacts located at the first side of the array region and electrically connected to the plurality of second word lines, wherein the plurality of first contacts and the plurality of second contacts are arranged in a staggered manner;
a plurality of first conductive lines electrically connected to the plurality of first contacts; and
a plurality of second conductive lines electrically connected to the plurality of second contacts, wherein the plurality of second conductive lines are extended from the peripheral region into the array region.

2. The test structure of claim 1, wherein the plurality of first conductive lines are located in the peripheral region and not located in the array region.

3. The test structure of claim 1, wherein
the plurality of first contacts and the plurality of second contacts are located in the peripheral region, and
the plurality of second contacts are located between the plurality of first contacts and the array region.

4. The test structure of claim 1, wherein
the plurality of first contacts are located between the plurality of first conductive lines and the plurality of first word lines, and
the plurality of second contacts are located between the plurality of second conductive lines and the plurality of second word lines.

5. The test structure of claim 1, wherein
the plurality of first contacts and the plurality of second contacts originate from a same material layer, and
the plurality of first conductive lines and the plurality of second conductive lines originate from a same material layer.

6. The test structure of claim 1, further comprising:
a plurality of third conductive lines electrically connected to the plurality of second conductive lines; and
a plurality of third contacts located between the plurality of third conductive lines and the plurality of second conductive lines and electrically connected to the plurality of third conductive lines and the plurality of second conductive lines.

7. The test structure of claim 6, wherein the plurality of third conductive lines and the plurality of third contacts are located in the array region.

8. The test structure of claim 1, further comprising:
a plurality of third contacts located at the second side of the array region and electrically connected to the plurality of first word lines;
a plurality of fourth contacts located at the second side of the array region and electrically connected to the plurality of second word lines, wherein the plurality of third contacts and the plurality of fourth contacts are arranged in a staggered manner;
a plurality of third conductive lines electrically connected to the plurality of third contacts, wherein the plurality of third conductive lines are extended from the peripheral region into the array region; and
a plurality of fourth conductive lines electrically connected to the plurality of fourth contacts.

9. The test structure of claim 8, wherein the plurality of fourth conductive lines are located in the peripheral region and not located in the array region.

10. The test structure of claim 8, wherein the plurality of third contacts and the plurality of fourth contacts are located in the peripheral region.

11. The test structure of claim 8, wherein the plurality of third contacts are located between the plurality of fourth contacts and the array region.

12. The test structure of claim 8, wherein
the plurality of third contacts are located between the plurality of third conductive lines and the plurality of first word lines, and
the plurality of fourth contacts are located between the plurality of fourth conductive lines and the plurality of second word lines.

13. The test structure of claim 8, further comprising:
a plurality of fifth conductive lines electrically connected to the plurality of third conductive lines; and
a plurality of fifth contacts located between the plurality of fifth conductive lines and the plurality of third conductive lines, and electrically connected to the plurality of fifth conductive lines and the plurality of third conductive lines.

14. The test structure of claim 13, wherein the plurality of fifth conductive lines and the plurality of fifth contacts are located in the array region.

15. The test structure of claim 1, further comprising:
a plurality of dummy word lines passing through the plurality of active regions and insulated from the substrate, wherein the plurality of dummy word lines comprise a plurality of first dummy word lines and a plurality of second dummy word lines arranged alternately;
a plurality of third contacts located at the first side of the array region and electrically connected to the plurality of first dummy word lines;
a plurality of fourth contacts located at the first side of the array region and electrically connected to the plurality of second dummy word lines, wherein the plurality of third contacts and the plurality of fourth contacts are arranged in a staggered manner;
a plurality of third conductive lines electrically connected to the plurality of third contacts; and
a plurality of fourth conductive lines electrically connected to the plurality of fourth contacts.

16. The test structure of claim 15, further comprising:
a plurality of fifth contacts located at the second side of the array region and electrically connected to the plurality of first dummy word lines;
a plurality of sixth contacts located at the second side of the array region and electrically connected to the plurality of second dummy word lines, wherein the plurality of fifth contacts and the plurality of sixth contacts are arranged in a staggered manner;
a plurality of fifth conductive lines electrically connected to the plurality of fifth contacts; and
a plurality of sixth conductive lines electrically connected to the plurality of sixth contacts.

17. The test structure of claim 16, wherein the plurality of third conductive lines, the plurality of fourth conductive lines, the plurality of fifth conductive lines, and the plurality of sixth conductive lines are located in the peripheral region and not located in the array region.

18. The test structure of claim 16, wherein the plurality of third contacts, the plurality of fourth contacts, the plurality of fifth contacts, and the plurality of sixth contacts are located in the peripheral region.

19. The test structure of claim 16, wherein
the plurality of third contacts are aligned with the plurality of first contacts in an arrangement direction of the plurality of dummy word lines, and
the plurality of fourth contacts are aligned with the plurality of second contacts in the arrangement direction of the plurality of dummy word lines.

20. A test structure, comprising:
a substrate comprising an array region and a peripheral region, wherein the array region has a first side and a second side opposite to each other;
an isolation structure located in the substrate, wherein the isolation structure defines a plurality of active regions in the substrate of the array region; and
a plurality of word lines passing through the plurality of active regions and insulated from the substrate, wherein the plurality of word lines comprise a plurality of first word lines and a plurality of second word lines arranged alternately;
a plurality of first contacts located at the first side of the array region and electrically connected to the plurality of first word lines;
a plurality of second contacts located at the first side of the array region and electrically connected to the plurality of second word lines, wherein the plurality of first contacts and the plurality of second contacts are arranged in a staggered manner;
a plurality of first conductive lines electrically connected to the plurality of first contacts; and
a plurality of second conductive lines electrically connected to the plurality of second contacts;
a plurality of third contacts located at the second side of the array region and electrically connected to the plurality of first word lines;
a plurality of fourth contacts located at the second side of the array region and electrically connected to the plurality of second word lines, wherein the plurality of third contacts and the plurality of fourth contacts are arranged in a staggered manner;
a plurality of third conductive lines electrically connected to the plurality of third contacts; and
a plurality of fourth conductive lines electrically connected to the plurality of fourth contacts.
